(19) United States
(12) Patent Application Publication
(10) Pub. No.: US 2014/0026937 A1
(43) Pub. Date: Jan. 30, 2014

(54) Semiconductor Heterostructure and Photovoltaic Cell Including Such A Heterostructure

(71) Applicants: Régis Andre, Claix (FR); Joël Bleuse, Seyssins (FR); Henri Mariette, Grenoble (FR)

(72) Inventors: Régis Andre, Claix (FR); Joël Bleuse, Seyssins (FR); Henri Mariette, Grenoble (FR)

(73) Assignees: Commissariat A L'Energie Atomique Et Aux Energies Alternatives, Paris (FR); CENTRE NATIONAL DE LA RECHERCHE SCIENTIFIQUE, Paris (FR)

(21) Appl. No.: 14/111,029

(22) PCT Filed: Apr. 6, 2012
(86) PCT No.: PCT/IB12/51720

§ 371 Date: Oct. 10, 2013

(30) Foreign Application Priority Data
Apr. 11, 2011 (FR) 1153146

(51) Int. Cl. H01L 31/0352

(52) U.S. Cl. CPC H01L 31/035236
USPC 136/244; 136/256

(57) ABSTRACT

The invention relates to a heterostructure including a first region (R1) made of a first n-doped semiconductor material, a second region (R2) made of a second p-doped semiconductor material and, between said first and second regions, a type-II superlattice (SR) made up of an alternation of layers (C1, C2) of a third and fourth semiconductor material, said layers being thin enough for the carriers to be displaced inside said superlattice, forming at least one electron mini-band (MBe) and one hole mini-band (MBh), the interfaces between the first region and the superlattice, between the layers of the superlattice and between the superlattice and the second region being mutually parallel. The invention also relates to a photovoltaic cell including such a heterostructure as an active element. The invention further relates to a solar panel including a combination of such photovoltaic cells.

The invention relates to a semiconductor heterostructure for use in photovoltaic cells. The invention also relates to a photovoltaic cell, in particular of the thin-film type, comprising such a heterostructure as an active element and to a solar panel comprising a combination of such cells.

Photovoltaic cells are devices converting the light energy transported by photons—generally of solar origin—into electrical energy in the form of a direct current. Several photovoltaic cells are generally combined in series (to raise the voltage) and in parallel (to increase the amperage) so as to form a solar panel or photovoltaic module. Several types of photovoltaic cells exist, employing various materials: bulk cells or thin-film cells, single-junction or multi-junction, with homojunction(s) or heterojunction(s), organic, etc. However, in all the configurations based on inorganic semiconductors, one or more PN junctions form the active element.

The most widespread photovoltaic cells are made of silicon—bulk silicon, or silicon deposited in the form of epitaxial layers, or in single crystal, polycrystalline, or amorphous form. This is because silicon offers considerable technological and economic advantages: it is a material available in large quantities, it is non-toxic and has a stable insulating oxide, and has been successfully used for decades. However, silicon is a poor absorber of light due to its indirect band structure; thus, the light absorption depth is relatively large (from 10 to 100 μm for wavelengths comprised between 800 and 1100 nm corresponding to the red/near infrared part of the solar spectrum), and the carriers must diffuse over a distance of the same order of magnitude before reaching an electrical contact. This limits the maximum photovoltaic energy conversion efficiency of silicon homojunction photovoltaic cells. Furthermore, this necessitates the use of thick, and therefore expensive, cells.

The use of direct band structure materials is not an entirely satisfactory alternative. Specifically, such materials absorb light more efficiently, thereby making it possible to limit the diffusion length of the photo-generated carriers (0.1-1 μm) and the thickness of the cells; but the direct band structure also facilitates recombination of minority carriers, which runs contrary to the intended goal of increasing the energy conversion efficiency.

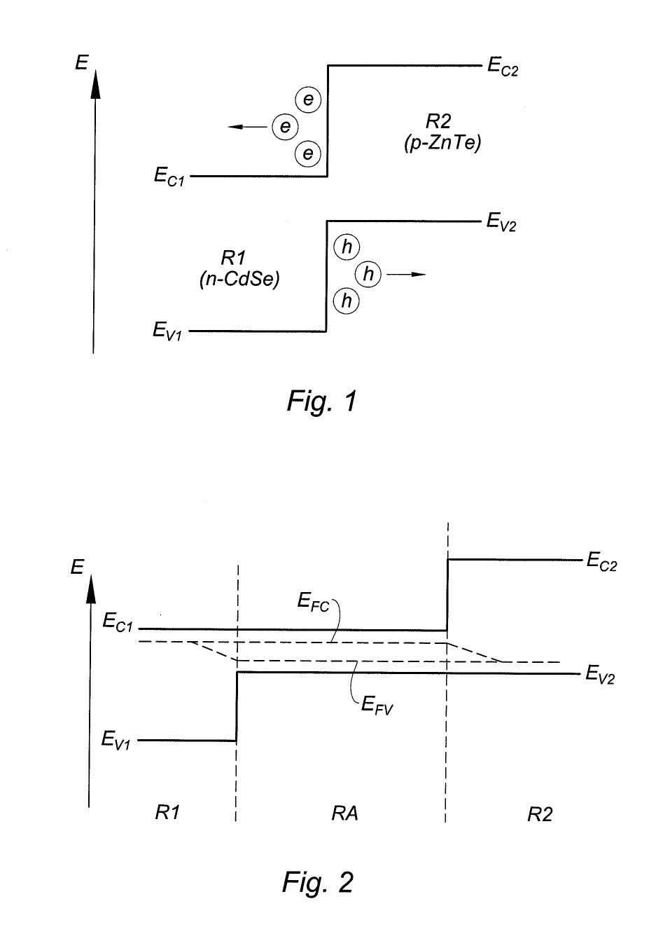

The problem posed by carrier recombination may be solved by replacing homojunctions made of direct band structure semiconductor material with heterojunctions, i.e. junctions in which the “p” and “n” regions are made of different semiconductor materials. FIG. 1 shows, very schematically, the band structure of an “n”-doped CdSe (left, reference R1)/“p”-doped ZnTe (right, reference R2) heterojunction. The alignment of the energy bands is such that:
the upper limit E_{V2} of the valence band of the ZnTe is comprised between the upper limit E_{V1} of the valence band and the lower limit E_{C1} of the conduction band of the CdSe ; and
the lower limit E_{C1} of the conduction band of the CdSe is comprised between the upper limit E_{V2} of the valence band and the lower limit E_{C2} of the conduction band of the ZnTe.

Under these conditions, the terms “type II alignment” or “type II heterostructure” are used. In such a structure, the electrons “e” of the conduction band see a potential minimum in the region R1 made of CdSe, whereas the holes “h” of the valence band see a potential maximum in the region R2 made of ZnTe. Thus the carriers remain separated, on opposite sides of the junction, and the recombination rate is low. It will moreover be noted that the light absorption threshold corresponds to the transitions between the valence band states localized in the ZnTe and the conduction band states localized in the CdSe, i.e. to an energy of about 1 eV, well below the widths of the band gaps of the two materials considered separately.

Unfortunately carrier separation, which limits the recombination rate, also acts as an obstacle to “low-energy” absorption of the photons. Specifically, this low-energy absorption (the most advantageous for photovoltaic applications) is possible only because of the existence of a weak penetration, via the tunnelling effect, of the wavefunctions of the electrons-localized, as mentioned above, in the CdSe-into the layer of ZnTe where the holes are localized, and vice versa. By analogy with indirect transitions in the reciprocal space of silicon, these transitions are said to be “indirect in real space”.

The following articles study the photovoltaic properties of ZnTe/CdSe heterojunctions:
P. A. Gashin and A. V. Simashkevich “ZnTe—CdSe Heterojunctions—II. Photoelectric and luminescent properties”, Phys. Stat. Sol. (a), 19, 615 (1973); and
N. G. Patel et al. “Fabrication and Characterization of ZnTe/CdSe Thin Films Solar Cells”, Cryst. Res. Technol, 29, 2, pages 247-252 (1994).

The following article studies the properties of other heterojunctions, also of type II: ZnO/ZnS and ZnO/ZnTe:

J. Schrier et al. “Optical Properties of ZnO/ZnS and ZnO/ZnTe heterostructures for photovoltaic applications”, Nano Lett., 2007, 7 (8), pp 2377-2382.

This article also studies type II heterostructures in the form of core/shell nanowires. On this topic, the reader may also refer to the article by Y. Zhang et al. ““Quantum Coaxial Cables” for Solar Energy Harvesting”, Nano Lett., 2007, 7(5), pp. 1264-1269. However, in this nanowire-based configuration the carriers are still generated in immediate proximity to a surface, where many recombination centers are also found, thereby reducing conversion efficiency. These nanowires are also more difficult to incorporate into photovoltaic cells than conventional planar heterostructures.

“Tandem ” solar cells comprise a multilayer of two heterostructures with band gaps of different widths in order to make better use of the range of the solar spectrum. See for example the article by P. Gashin et al . “n-ZnSe/p-ZnTe/n-CdSe tandem solar cells”, Solar Energy Materials and Solar Cells 46 (1997) 323-331. However, this does not allow the aforementioned drawbacks of heterojunction photovoltaic cells to be remedied.

The article by A. Mascarenhas et al. “Lateral Superlattice Solar Cells”, AIP Conf. Proc., Volume 404, pp. 303-308, 5 Apr. 1997, proposes a photovoltaic cell in which the active region is formed by a type II superlattice to which a “p”-doped region and an “n”-doped region are laterally attached. Thus, the planes of the layers of the superlattice are perpendicular to the interfaces between said superlattice and the aforementioned “p” and “n” regions. Electron/hole pairs are generated in the layers of said superlattice by transitions that are direct both in real space and in reciprocal space; the electrons diffuse rapidly in the layers having a conduction band of lower energy, and the holes in those having a valence band of higher energy; then these carriers diffuse in the plane of the layers, toward the “n” region and the “p” region respectively, while remaining separate, which minimizes the recombination rate.

Whatever the advantages of such a structure may be, it promises to be extremely difficult to manufacture and, as far as the inventors are aware, it has never been made in practice.

Another theoretical solution to the problem of increasing the energy conversion efficiency of solar cells is proposed by P. WUrfel in chapter 6, paragraph 2 of his work “Physics of Solar Cells—From Principles to New Concepts”, Wiley-VCH Verlag GmbH & Co KGaA, Weinheim, 2005. This structure, schematically illustrated in FIG. 2, comprises an “n”-doped region R1, a “p”-doped region R2 and an absorption region RA between the two. Both the region R1 and the region R2 have a wider band gap than that of the absorption region. More precisely, the upper limit of the valence band of the absorption region is aligned with that, indicated by E_{V2}, of the region R2, whereas the lower limit of its conduction band is aligned with that, indicated by E_{C1}, of the region R1. The upper limit E_{V1} of the valence band of the region R1 is located at an energy level below E_{V2} and the lower limit E₂ of the conduction band of the region R2 is located at an energy level above E_{C1}. The references E_{FC} and E_{FV} indicate the quasi-Fermi levels of the absorption region under illumination for the electrons and holes, respectively. Inside the absorption region, the photogenerated electrons drift toward the left following a gradient—which cannot be seen in the figure—of E_{FC}, whereas the photogenerated holes drift to the right following a gradient—which also cannot be seen in the figure—of E_{FV}. On the left, at the interface RA/R1, the step formed by the valence band forms a barrier for the holes, whereas the alignment of the conduction bands ensures rapid evacuation of the electrons e. Reciprocally on the right, at the interface RA/R2, the step formed by the conduction band forms a barrier for the electrons, whereas the alignment of the valence bands ensures rapid evacuation of the holes h.

The band structure illustrated in FIG. 2 is purely theoretical, and does not correspond to any known physical system of the prior art. So-called “de Gratzel” cells are the best known approximation to this structure. These cells are based on a porous structure of TiO₂ nanoparticles (forming the region R1) coated with a thin layer of dye (absorber RA) and submerged in an electrolyte (forming the region R2). Nevertheless these cells have many drawbacks: the electrolyte is generally a liquid, requiring an impermeable encapsulation, the transport of electrons from one nanoparticle to another is difficult, there is little flexibility where the adaptation of the dye to the solar spectrum is concerned, and, above all, the dye is easily degraded by ultraviolet light.

The invention aims to overcome the aforementioned drawbacks of the prior art.

One subject of the invention, making it possible to achieve this goal, is a heterostructure comprising a first region made of an n-doped first semiconductor material, a second region made of a p-doped second semiconductor material, and, between said first and second regions, a superlattice formed by an alternation of layers of a third and a fourth semiconductor material, the interfaces between the first region and the superlattice, between the layers of the superlattice, and between the superlattice and the second region being mutually parallel; characterized in that: the layers are thin enough for the carriers to be delocalized inside said superlattice, forming at least one electron mini-band and one hole mini-band; in that the upper limit of the valence band of said fourth material is comprised between the upper limit of the valence band and the lower limit of the conduction band of said third material, and the lower limit of the conduction band of said third material is comprised between the upper limit of the valence band and the lower limit of the conduction band of said fourth material, in such a way that the third and fourth material form type II heterojunctions; in that the lower limit of the conduction band of said first material is comprised between that of the conduction band of said third material and that of the least energetic electron mini-band in said superlattice, whereas the upper limit of the valence band of said second material is comprised between that of the valence band of said fourth material and that of the most energetic hole mini-band in said superlattice ; in that the band gap of said first material is wide enough to form a potential barrier for the holes at the interface between said first region and said superlattice ; and in that the band gap of said second material is wide enough to form a potential barrier for the electrons at the interface between said second region and said superlattice.

In order for a potential barrier for the holes to form between said first region and the superlattice, the upper limit of the valence band of said first material must be less than the lower limit of the hole mini-band by at least 0.1-0.2 eV. Preferably, the upper limit of the valence band of the first material will be less than or equal to that of the valence band of said third material.

Likewise, in order for a potential barrier for the electrons to form between said second region and the superlattice, the lower limit of the conduction band of said second material must be greater than the upper limit of the electron mini-band by at least 0.1-0.2 eV. Preferably the lower limit of the conduction band of the second material will be greater than or equal to that of the conduction band of said fourth material.

In particular, said first material may be identical to said third material, except where its doping is concerned, and said second material may be identical to said fourth material, except where its doping is concerned.

According to various embodiments of the heterostructure of the invention:
said layers forming a superlattice may have thicknesses comprised between 1 and 10 nm.
Said superlattice may have a total thickness comprised between 300 nm and 1500 nm.
Said superlattice may be formed by intrinsic semiconductor layers. The term “intrinsic” is understood to mean a semiconductor material having a concentration of impurities able to act as dopants of less than or equal to 10¹⁶ cm⁻³ and preferably of less than or equal to 10¹⁵ cm⁻³.
Said superlattice and at least one from among said first zone and said second zone may take the form of thin films deposited on a substrate.
Said first, second, third and fourth materials may be inorganic semiconductors. More particularly, at least said third and fourth materials may be type II-VI or III-V semiconductors, and may especially be chosen from among the following pairs: CdSe/ZnTe; CdS/ZnTe ; InP/GaAs; InP/GaSb; GaN/AlAs; GaN/ZnTe; ZnO/ZnSe; ZnO/ZnTe; ZnO/CdSe; and ZnO/CdTe. The following pairs are particularly preferred: CdSe/ZnTe; CdS/ZnTe; InP/GaAs and InP/GaSb.
The layers forming said superlattice, and their interfaces with said first and second regions, may be planar.

Another subject of the invention is a photovoltaic cell comprising a heterostructure such as described above as the active element.

Yet another subject of the invention is a solar panel comprising a combination of such photovoltaic cells.

Other features, details and advantages of the invention will become apparent on reading the following description, given by way of example and with reference to the appended drawings which show, respectively:

FIG. 1, the band structure of a type II heterostructure;

FIG. 2, the band structure of an ideal photovoltaic cell according to the aforementioned work by P. Würfel;

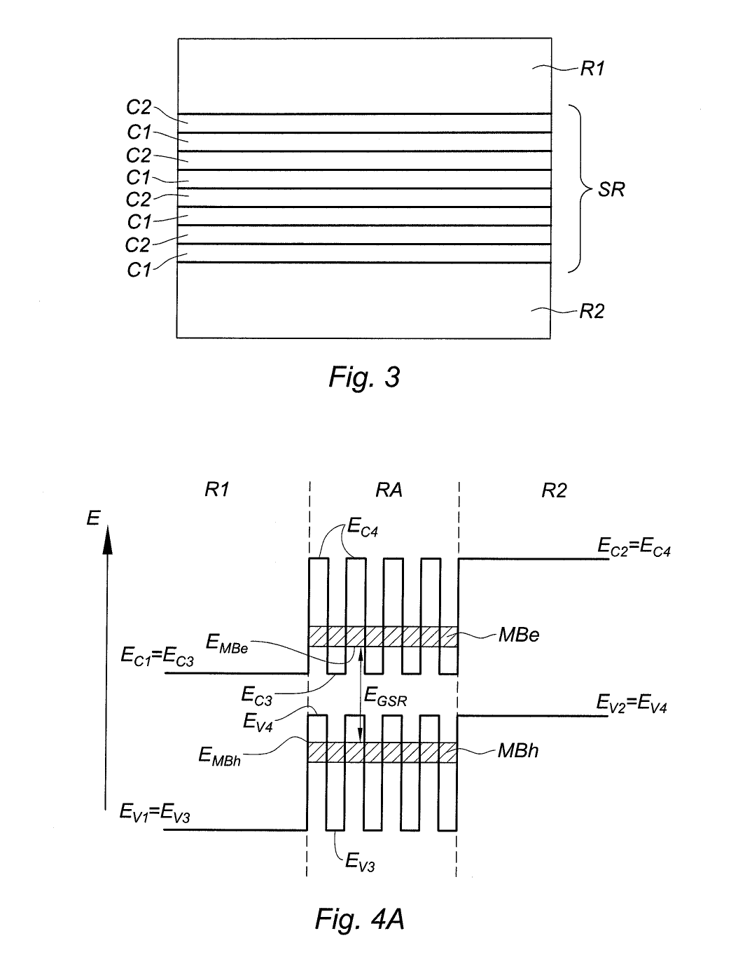

FIG. 3, a schematic representation of a heterostructure according to one embodiment of the invention;

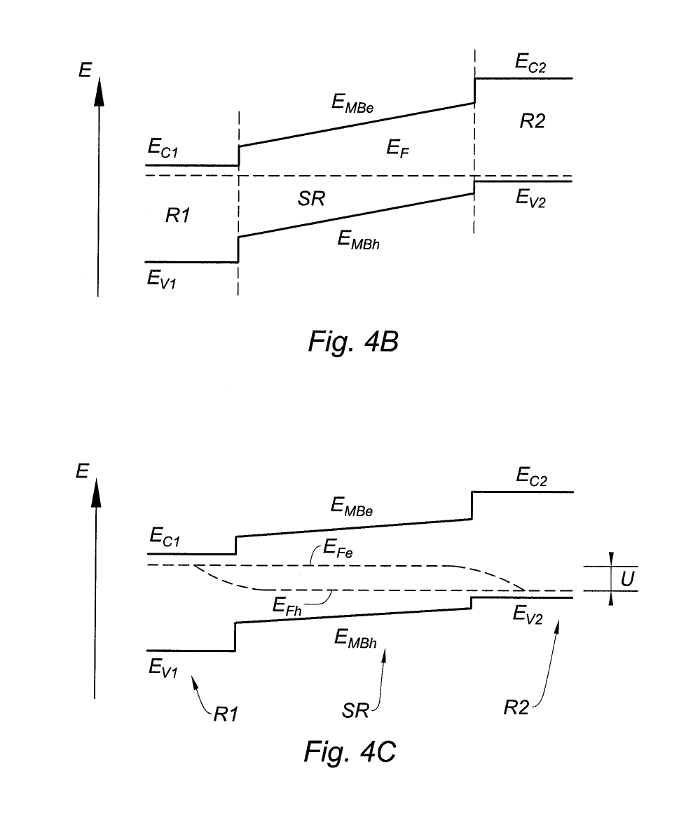

FIGS. 4A, 4B and 4C, three representations of the band structure of the heterostructure in FIG. 3 under three different conditions, namely: under flat band condition, at equilibrium and under illumination;

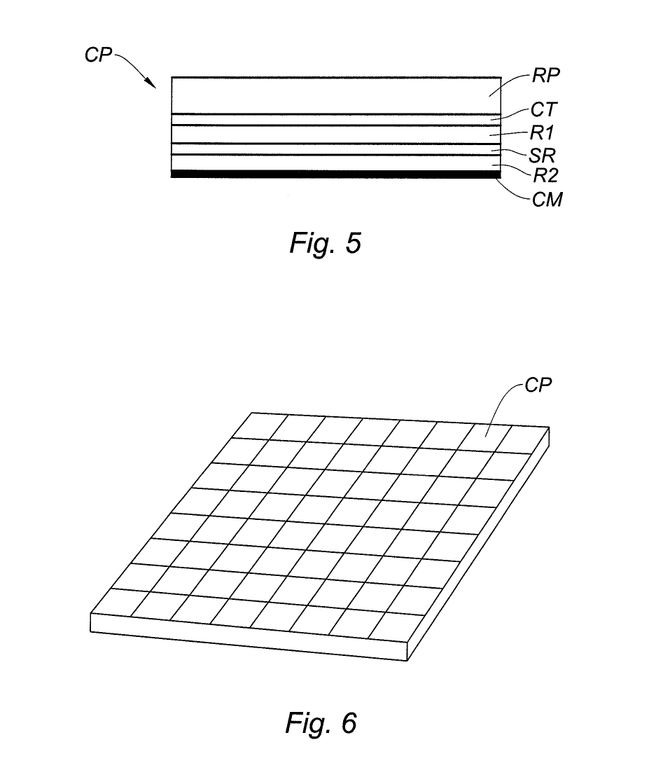

FIG. 5, a photovoltaic cell according to one embodiment of the invention; and

FIG. 6, a solar panel according to one embodiment of the invention.

Certain concepts used in the following text should first be defined.

A heterostructure is a structure formed by semiconductors having band gaps of different widths, and making mutual contact. The junction between two semiconductor materials having band gaps of different widths is a heterojunction.

A superlattice is a periodic structure formed by the alternation of layers of different materials. Only the case in which these materials are semiconductors having different band gaps will be referred to in the present invention. Such a superlattice may also be considered as an assembly of identical mutually coupled quantum wells. If the coupling between the quantum wells is strong enough (i.e. if the layers are thin enough, generally about a few nanometers in thickness) their discrete energy levels combine into energy bands which, for an infinite superlattice, would be continuous; the term “mini-bands” is used, these bands corresponding to electronic states delocalized over the whole volume of the superlattice. This, on a different scale, is the same effect that leads to the formation of the band structure of crystals.

A photovoltaic cell is understood to be a device intended to generate, via a photovoltaic effect, electrical energy from sunlight, and particularly from sunlight received on the ground. Such a device must therefore be sensitive to visible and near-infrared radiation.

A basic idea behind the invention is that a superlattice behaves like an “effective material” having a direct band structure and a tunable, one might say “bespoke”, band gap width. Such a material may be designed to act as the absorber in the theoretical structure in FIG. 2.

FIG. 3 shows, very schematically, a heterostructure according to an embodiment of the invention. This heterostructure comprises a region R1 of “n”-doped CdSe, a region R2 of “p”-doped ZnTe (in both cases, the doping density is of the order of 10¹⁸-10²⁰ cm⁻³) and, between the two, a superlattice SR formed by an alternation of undoped layers of these two materials (C₁: layers of CdSe; C₂: layers of ZnTe). The overall thickness of the superlattice must be as small as possible, while being large enough to ensure practically total absorption of the incident sunlight; as the materials considered here have a direct band structure in reciprocal space, the ideal thickness is about 600 nm.

In the embodiment in FIG. 3, the first region R1 is composed of the same material as the layers C₁ (with, if required, a different doping), and the second region R2 is composed of the same material as the layers C₂ (also with doping which may, if required, be different). As will be explained in detail below, this constraint may be relaxed.

The FIG. 4A shows a representation of the band structure of the heterostructure illustrated in FIG. 3. Out of a concern for generality, the following have been denoted as follows:
the lower limit of the conduction band and the upper limit of the valence band of the material of the first region R1, E_{C1} and E_{V1}, respectively;
the lower limit of the conduction band and the upper limit of the valence band of the material of the second region R2, E_{C2} and E_{V2}, respectively;
the lower limit of the conduction band and the upper limit of the valence band of the material of the layers C₁, E_{C3} and E_{V3}, respectively;
the lower limit of the conduction band and the upper limit of the valence band of the material of the layers C₂, E_{C4} and E_{V4}, respectively.

In this case:

E_{C1}=E_{C3}; E_{V1}=EV₃; and

E_{C2}=E_{C4}; E_{V2}=EV₄,

but this need not be true in general. In particular, it may be advantageous to make the first region R1 from a material having an energy E_{C1} greater than E_{C3} and closer to E_{MBe} so as to reduce, or even suppress, the potential jump at the interface R1/SR. Likewise, it may be advantageous to make the second region R2 from a material having an energy E_{V2} less than E_{V4} and closer to E_{MBh} so as to reduce, or even suppress, the potential jump at the interface SR/R2. This may be obtained by using a first (respectively: second) material of a chemical composition close to that of the third (respectively: fourth) material, but comprising an impurity that slightly modifies its band width. For example, in the case where the third material is CdSe, E_{C1} may be increased in relation to E_{C3} by making the region R1 from MnₓCd₁₋ₓSe or MgₓCd₁₋ₓSe, where x is about a few percent.

The band structure in FIG. 4A shows that the heterostructure in FIG. 3 is a type II heterostructure. The layers forming the superlattice SR are small enough for the carriers to be substantially delocalized; the ideal period (thickness of a layer C₁ plus thickness of a layer C₂) of the superlattice is of about 4 nm; the layers C₁ and C₂ may have the same thickness or different thicknesses. Under these conditions, the energy levels of the electrons and of the holes in the superlattice form “mini-bands” ; in FIG. 4A, only the least energetic electron mini-band (MBe) and the most energetic hole mini-band (MBh) have been shown. The upper limit E_{MBh} of the miniband MBh and the lower limit E_{MBe} of the mini-band MBe define an effective band gap E_{GSR} the width of which is tunable within a range of 1 to 2 eV by altering the thicknesses of the layers of the superlattice, and therefore easily adaptable to the solar spectrum. In the following text, the superlattice may simply be likened to an effective semiconductor material in which E_{MBh} constitutes the upper limit of the valence band and E_{MBe} the lower limit of the conduction band. The band structure thus obtained is very similar to that in FIG. 2, except that the levels E_{C1} and E_{MBe} are not exactly aligned, just like the levels E_{V2} and E_{MBh}. However, the levels of the electron mini-band are resonant with energy levels (with wave vector k≠0) in the conduction band of the region R1; likewise, the levels of the hole mini-band are resonant with energy levels (with wave vector k≠0) in the valence band of the region R2. This ensures a very rapid transfer of the photogenerated electrons toward R1 and of the photogenerated holes toward R2.

The diagram in FIG. 4A is of the “flat band” type, ignoring the effect of charge carrier distribution in the structure. In contrast, this effect is taken into account in FIGS. 4B and 4C.

FIG. 4B concerns the case where the heterostructure is under equilibrium conditions, in the absence of illumination, with no current passing through it and no voltage across the terminals. In such an equilibrium situation, the Fermi level E_{F} must be constant in the whole structure, thereby leading to a reorganization of the charges and therefore to a sloping of the bands in the superlattice (shown here as an effective material.)

Under illumination, the establishment of a population of electrons and holes, out of equilibrium, in the superlattice where photon absorption and therefore carrier pair generation takes place, separates the Fermi level into two components: electron quasi-Fermi level, E_{Fe}, and hole quasi-Fermi level E_{Fh}. This produces a shift in the Fermi level between the ends of the structure, as illustrated in FIG. 4C. The difference between these levels at the ends is equal to the voltage in an open circuit across the device terminals (denoted U in the figure). This is a non-equilibrium situation that can, if the circuit is closed, produce an electron current toward the left and a hole current toward the right. This description exhibits similarities, from the point of view of the physical effects coming into play, with the case of a p-n junction under illumination. With respect to the case of a simple p-n junction, however, evacuation of the carriers toward the regions R1 and R2 is promoted, and consequently their recombination is made less probable.

The heterostructure in FIG. 3 may be made by conventional epitaxy techniques, all the more easily since the separation in the lattice parameter between CdSe and ZnTe is about 1% only. For example, the region R2 may be formed from a substrate of p-doped ZnTe, on which alternating layers of intrinsic CdSe and ZnTe are deposited to form the superlattice SR, a thicker layer of n-doped CdSe then being deposited to form the region R1. As a variant, the layer R2 may in turn be an epitaxial layer deposited on a conductive substrate, or on a conductive layer acting as electrode, deposited in turn on an insulating substrate.

Other material pairs may be used in place of CdSe and ZnTe; in particular, these may be inorganic type II-VI or III-V semiconductor pairs, advantageously with a direct band structure to benefit from the high absorption coefficient characterizing these materials. The main conditions to observe are the following:
these materials must form type II heterostructures. Neither type I heterostructures (characterized by the conditions: E_{C3}>E_{C4}; E_{V3}<E_{V4}) nor type III heterostructures (E_{V3}>E_{C4}>E_{V4}) are suitable for photovoltaic applications. Readers should be aware that the terminology used in the scientific literature is not perfectly standardized, and that certain authors use the expression “type II” extensively, also encompassing structures which are really type III structures.
The band gap at the interface of the two materials must be compatible with a good use of the spectrum of the incident light. When this spectrum is the solar spectrum, this band gap must be below 1.8 eV.
The separation in the lattice parameter must be small enough to allow the formation of heterojunctions with few defects (typically less than 10%, even if larger separations may be tolerated in certain cases).
The layers forming the superlattice must be thin enough for the carriers to be delocalized over the whole volume of the latter. As a general rule this condition is satisfied for periods of the superlattice not exceeding 10 nm; a lower limit at this period may be estimated at around 1 nm. FIG. 6 of the aforementioned article by A. Mascarenhas et al. shows a heterostructure that bears a superficial resemblance to that of the invention, but in which the layers forming the vertical “superlattice” are wider, which prohibits the formation of mini-bands of delocalized electron states, which are essential to the invention. As the article expressly indicates, such a structure does not offer any particular advantage.

Of course, the optimal width of the superlattice depends on the materials being considered, and on the nominal spectrum of the incident light. As a general rule, this thickness will possibly be comprised between 300 nm and 1500 nm (1.5 μm).

The doping density in the regions R1 and R2 will depend on the application being considered. It is not essential that the superlattice be intrinsic. The table below presents a non-limiting list of pairs of materials that may be used to make a heterostructure according to the invention. The four first pairs are particularly preferred because of the small separation in their lattice parameters. The band gap widths are indicative and drawn from the scientific literature in the field; hence, in certain cases, a range of values is indicated instead of a single value.

| | Lattice parameter | Band gap width | |
|---|---|---|---|
| Materials | separation | at the interface | |
| CdSe/ZnTe | 1% | 1.09 | eV |
| CdS/ZnTe | 4% | 1.42 | eV |
| InP/GaAs | 4% | 0.98 | eV |
| InP/GaSb | 4% | 0.41 | eV |
| GaN/AlAs | 20% | 1.73 | eV |
| GaN/ZnTe | 29% | 1.42 | eV |
| ZnO/ZnSe | 20% | 1.7-1.8 | eV |
| ZnO/ZnTe | 28% | 1-1.1 | eV |
| ZnO/CdSe | 28% | 1.7-1.8 | eV |
| ZnO/CdTe | 34% | 1-1.1 | eV |

As indicated above, it is not essential for the first region R1 and the layers C₁ (the second region R2 and the layers C₂, respectively) to be composed of the same material. In the most general case, the first region R1, the second region R2, the layers C₁ and the layers C₂ will be composed respectively of a first, second, third and fourth semiconductor material with band limits E_{C1}/E_{V1}; E_{C2}/E_{V2}; E_{C1}/E_{C2}; E_{C3}/E_{V3} and E_{C4}/E_{V4}, respectively. In this case, it is necessary for:
the lower limit of the conduction band of said first material to be comprised between that of the conduction band of said third material and that of the least energetic electron mini-band in said superlattice: E_{C3}≦E_{C1}≦E_{MBe}; and for
the upper limit of the valence band of said second material to be comprised between that of the valence band of said fourth material and that of the most energetic hole mini-band in said superlattice: E_{V4}≦E_{V2}≦E_{MBh}.

It is also necessary for a potential barrier for the holes to form between the first region and the superlattice (since holes photogenerated in the active region must not diffuse into the first region, but only into the second), and reciprocally for a potential barrier for the electrons to form between the second region and the superlattice (since electrons photogenerated in the active region must not diffuse into the second region, but only into the first).

As mentioned above, for this to happen it is necessary for the upper limit of the valence band of said first material (E_{V1}) to be less than the lower limit of the hole mini-band by at least 0.1-0.2 eV, and for the lower limit of the conduction band of said second material (E_{C2}) to be greater than the upper limit of the electron mini-band by at least 0.1-0.2 eV.

Preferably: E_{V1}≦E_{V3} and E_{C2}≧E_{C4}.

FIG. 5 shows a cutaway view of a photovoltaic cell CP according to an embodiment of the invention. This cell comprises, as an active region (responsible for the absorption of the light and for the carrier generation), a heterostructure of the type in FIG. 3. A metallic layer CM forms an ohmic contact with the substrate R2 made of ZnTe. A layer CT of a transparent conductive material (for example, zinc or tin oxide) deposited on the region R1 of CdSe forms the opposite electrode. A glass coating RP protects the assembly. As a variant, the region R2 may in turn be a thin film, having a thickness of a few micrometers or less, deposited on the layer CM, deposited in turn on an insulating substrate, for example made of glass.

A photovoltaic cell according to another embodiment may also have a “tandem” structure, formed by a superposition of two heterostructures, of the type in FIG. 3, designed to make use of the various parts of the solar spectrum.

FIG. 6 shows a solar panel, or photovoltaic module, formed by a series combination and a parallel combination of photovoltaic cells of the type illustrated in FIG. 5. Except as regards the cells themselves, such a panel or module has a conventional structure.

1. A heterostructure comprising a first region made of an n-doped first semiconductor material, a second region made of a p-doped second semiconductor material, and, between said first and second regions, a superlattice formed by an alternation of layers of a third and a fourth semiconductor material, the interfaces between the first region and the superlattice, between the layers of the superlattice, and between the superlattice and the second region being mutually parallel; characterized in that:
said layers are thin enough for the carriers to be delocalized inside said superlattice forming at least one electron mini-band (MBe) and one hole mini-band (MBh); in that the upper limit (E_{V4}) of the valence band of said fourth material is comprised between the upper limit (E_{V3}) of the valence band and the lower limit (E_{C3}) of the conduction band of said third material, and the lower limit (E_{C3}) of the conduction band of said third material is comprised between the upper limit (E_{V4}) of the valence band and the lower limit (E_{C4}) of the conduction band of said fourth material, in such a way that the third and fourth material form type II heterojunctions; in that:
the lower limit (E_{C1}) of the conduction band of said first material is comprised between that (E_{C3}) of the conduction band of said third material and that (E_{MBe}) of the least energetic electron mini-band in said superlattice, whereas the upper limit (E_{V2}) of the valence band of said second material is comprised between that (E_{V4}) of the valence band of said fourth material and that (E_{MBh}) of the most energetic hole mini-band in said superlattice; in that the band gap of said first material is wide enough to form a potential barrier for the holes at the interface between said first region and said superlattice; and in that;
the band gap of said second material is wide enough to form a potential barrier for the electrons at the interface between said second region and said superlattice.

2. The heterostructure as claimed in claim 1, in which said first material is identical to said third material, except where its doping is concerned, and said second material is identical to said fourth material, except where its doping is concerned.

3. The heterostructure as claimed in claim 1, in which said layers forming a superlattice have thicknesses comprised between 1 and 10 nm.

4. The heterostructure as claimed in claim 1, in which said superlattice has a total thickness comprised between 300 nm and 1500 nm.

5. The heterostructure as claimed in claim 1, in which said superlattice is formed by intrinsic semiconductor layers.

6. The heterostructure as claimed in claim 1, in which said superlattice and at least one from among said first zone and said second zone take the form of thin films deposited on a substrate.

7. The heterostructure as claimed in claim 1, in which said first, second, third and fourth material are inorganic semiconductors.

8. The heterostructure as claimed in claim 7, in which at least said third and said fourth material are type II-VI or III-V semiconductors.

9. The heterostructure as claimed in claim 8, in which said third and said fourth semiconductor material are chosen from among the following pairs:
CdSe/ZnTe;
CdS/ZnTe;
InP/GaAs;
InP/GaSb;
GaN/AlAs;
GaN/ZnTe;
ZnO/ZnSe;
ZnO/ZnTe;
ZnO/CdSe; and
ZnO/CdTe.

10. The heterostructure as claimed in claim 8, in which said third and said fourth semiconductor material are chosen from among the following pairs: CdSe/ZnTe; CdS/ZnTe; InP/GaAs and InP/GaSb.

11. The heterostructure as claimed in claim 1, in which the layers forming said superlattice, and their interfaces with said first and second regions, are planar.

12. A photovoltaic cell (CP) comprising a heterostructure as claimed in claim 1 as an active element.

13. A solar panel comprising a combination of photovoltaic cells as claimed in claim 12.
